(19) United States
(12) Patent Application Publication
(10) Pub. No.: US 2007/0170468 A1
(43) Pub. Date: Jul. 26, 2007

(54) Method for manufacturing a semiconductor substrate and a method for manufacturing a semiconductor device and the semiconductor device manufactured thereby

(75) Inventor: Toshiki Hara, Suwa-shi (JP)

Correspondence Address: ADVANTEDGE LAW GROUP, LLC, 1928 E. COBBLESTONE RD., SUITE 100, SPRINGVILLE, UT, 84663, US

(73) Assignee: Seiko Epson Corporation, Tokyo (JP)

(21) Appl. No.: 11/653,502

(22) Filed: Jan. 16, 2007

(30) Foreign Application Priority Data
Jan. 23, 2006 (JP) 2006-013605

(51) Int. Cl. H01L 27/10

(52) U.S. Cl. 257/211

(57) ABSTRACT

A method for manufacturing a semiconductor substrate includes: forming an element isolation layer on a semiconductor base material for separating an element region from the other regions; forming a first semiconductor layer on the semiconductor base material; forming a second semiconductor layer on the first semiconductor layer, the second semiconductor layer having an etching selection ratio smaller than that of the first semiconductor layer; forming support holes by removing portions of the first semiconductor layer and the second semiconductor layer, the portions corresponding to regions for the support holes; forming a support forming layer on the semiconductor base material such that the support holes and the second semiconductor layer are covered by the support forming layer; forming exposed surfaces such that portions of the support forming layer other than a region including the support holes and the element region are etched to expose a support and portions of end portions of the first semiconductor layer and the second semiconductor layer which are positioned below the support; forming a first cavity portion between the second semiconductor layer and the semiconductor base material of the element region by etching the first semiconductor layer through the exposed surfaces; forming a buried insulating layer within the first cavity portion; and removing portions of the support positioned on the second semiconductor layer by providing a planarization treatment above the second semiconductor layer; in which forming the support holes includes forming the support holes at first regions on the element isolation layer.

### BACKGROUND

1. Technical Field

The invention relates to a method for manufacturing a semiconductor substrate and a method for manufacturing a semiconductor device and the semiconductor device manufactured thereby, more specifically, to a technique for forming a Silicon On Insulator (SOI) structure on the semiconductor substrate.

2. Related Art

The above stated method for manufacturing the semiconductor substrate utilizes a Separation by Bonding Si Islands (SBSI) method to partially form a SOI layer on a bulk silicon substrate and further to form a SOI transistor on this SOI layer as taught, for example, by T. Sakai et al., Second International SiGe Technology and Device Meeting, Meeting Abstract, pp. 230-231, May (2004). Such a partial formation of the SOI layer realizes, for example, a low cost manufacturing of the SOI transistor.

Explained next is a method for forming the SOI structure on the bulk silicon substrate. Initially, in accordance with the above stated SBSI method, a silicon germanium (SiGe) layer and a silicon (Si) layer are deposited on the bulk silicon substrate by an epitaxial growth and support holes for a support at an element region of the SOI layer are formed. After an oxide film or the like is grown over those layers and holes, the adjacent oxide film, silicon layer and silicon germanium layer are subjected to a dry etching process in order to create a shape of an element forming region. Then, as illustrated in FIG. 10, the silicon germanium layer (not shown here) is selectively etched using a fluoronitric acid, resulting in that the silicon layer 101 is supported by the support 102 and a cavity portion 103 is created below the silicon layer 101. Then, an insulating layer (not shown here) such as SiO₂ or the like is buried into the cavity portion 103 to form a Buried Oxide (BOX) layer between the bulk silicon substrate 104 and the silicon layer 101. Thereafter, a surface of the bulk silicon substrate 104 is subjected to a planarization treatment to have a surface of the silicon layer 101 exposed, thereby forming the SOI structure on the bulk silicon substrate 104.

However, when the BOX layer is formed by a thermal oxidation method, the support 102 is heated to be expanded or shrunk, for example, in arrow directions. Accordingly, the silicon layer 101, which is supported by the support 102, is applied with a stress, resulting in causing a problem that there occurs differences of properties (for example, of a mobility) in transistors.

### SUMMARY

An advantage of some aspects of the invention is to provide a method for manufacturing a semiconductor substrate and a method for manufacturing a semiconductor device and the semiconductor device manufactured thereby, which can achieve a constant transistor properties.

According to an aspect of the invention, the method for manufacturing the semiconductor substrate includes a process for forming an element isolation layer on a semiconductor base material in order to separate an element region from the other regions; a process for forming a first semiconductor layer on the semiconductor base material; a process for forming on the first semiconductor layer a second semiconductor layer having an etching selection ratio smaller than that of the first semiconductor layer; a process for removing portions of the first semiconductor layer and the second semiconductor layer corresponding to regions for support holes in order to form the support holes; a process for forming a support forming layer on the semiconductor base material in such a manner the support forming layer covers the support holes and the second semiconductor layer; a process for etching portions of the support forming layer except for regions including the support holes and the element region to have the support and portions of end portions of the first semiconductor layer and the second semiconductor layer positioned below the support be exposed in order to form exposed surfaces; a process for etching the first semiconductor layer through the exposed surfaces thereof to create a first cavity portion between the second semiconductor layer of the element region and the semiconductor base material; a process for forming a buried insulating layer within the first cavity portion; and a process for providing a planarizaiton treatment above the second semiconductor layer and removing portions of the support positioned on the second semiconductor layer, in which the process for forming the support holes forms support holes at first regions on the element isolation layer.

According to the above stated method, since the support holes are formed at the first regions on the element isolation layer, such a structure is provided that portions of the poricrystallin first semiconductor layer and the second semiconductor layer formed on the element isolation layer between the support and side surfaces of the single crystal second semiconductor layer formed on the semiconductor base material by forming the support forming layer over the support holes to complete the support. Accordingly, when the first semiconductor layer below the support is removed by the etching process, the portions of the polycrystalline first semiconductor layer and the second semiconductor layer on the element isolation layer below the support can be removed concurrently, thereby making it possible to create spaces between the support and the side surfaces of the single crystal second semiconductor layer. With the above stated structure, when the buried insulating layer is buried in lieu of the first semiconductor layer, even if the support expands and contracts due to application of heat and thereby the stress is applied onto the second semiconductor layer, the stress applied to the second semiconductor layer can be released by the spaces. As such, the stress applied to the second semiconductor layer is relaxed to suppress differences of properties (specifically, of the mobility) in transistors.

According to the method for manufacturing the semiconductor substrate of the invention, the first regions are regions in which it is possible to form the second cavity portions between side surfaces of the second semiconductor layer and the support at the element region during the process for forming the first cavity portion.

With the above stated method, even if the stress is applied to the second semiconductor layer owing to the expansion and the contraction of the support caused by the heat applied while the buried insulating layer is buried in lieu of the first semiconductor layer, the stress applied to the second semiconductor layer can be relaxed by the second cavity portions because the second cavity portions are formed between the side surfaces of the second semiconductor layer and the support. As such, the stress applied to the second semiconductor layer can be suppressed and thus the differences of properties in transistors can be suppressed.

According to the method for manufacturing the semiconductor substrate of the invention, the second cavity portions are buffering regions capable of providing a relaxation of the stress applied to the second semiconductor layer at the element region in the process of forming the buried insulating layer.

With the above stated method, since the second cavity portions are the buffering regions capable of providing the relaxation of the stress applied to the second semiconductor layer, even if the support is applied with heat, the stress applied to the second semiconductor layer can be released within the second cavity portions.

According to the method for manufacturing the semiconductor substrate of the invention, the process for forming the support holes forms the support holes at positions where spaces are left between the support and the side surfaces of the second semiconductor layer when the buried insulating layer is buried in the process of forming the buried insulating layer.

With the above stated method, since the support holes are formed at positions where spaces are left between the side surfaces of the second semiconductor layer and the support when the buried insulating layer is buried into the first cavity portion in the process of forming the support holes, even if the support expands and contracts due to the continuous heating after the process of forming the buried insulating layer, the stress applied to the second semiconductor layer can be buffered.

According to the method for manufacturing the semiconductor substrate of the invention, the first semiconductor layer is a silicon germanium layer and the second semiconductor layer is a silicon layer.

According to the above stated method, since the silicon has the etching selection ratio smaller than that of the silicon germanium, such an etching that the silicon germanium layer is selectively removed, with the silicon layer being left, can be done. Accordingly, the cavity portion to be buried by the buried insulating layer can be formed below the silicon layer. In addition, the poricrystallin silicon germanium layer and the silicon layer formed on the element isolation layer are removed concurrently in order to form the cavity portions between the support and the side surfaces of the silicon layer.

According to another aspect of the invention, the method for manufacturing the semiconductor device includes a process for forming a transistor on the second semiconductor layer after the method for manufacturing the semiconductor substrate is done.

With the above stated method, the stress applied to the second semiconductor layer can be relaxed and thus it is possible to provide the method for manufacturing the semiconductor device which can suppress the occurrence of the differences of properties in transistors.

According to a further aspect of the invention, the semiconductor device having the SOI structure includes a buried insulating layer which is buried on the semiconductor base material in lieu of the first semiconductor layer, the second semiconductor layer on the buried insulating layer, and the support for supporting the second semiconductor layer, in which the support holes for forming the support are formed at the first regions on the element isolation layer.

With the above stated structure, since the support holes are formed at the first regions on the element isolation layer, the semiconductor device has a construction including the portions of the polycrystalline first semiconductor layer and the second semiconductor layer between the support and the side surfaces of the single crystal second semiconductor layer below the support. Therefore, when the single crystal first semiconductor layer is removed by the etching process, the portions of the polycrystalline second semiconductor layer and the portions of the first semiconductor layer can be removed concurrently, thereby being capable of forming the cavity portions between the support and the side surfaces of the second semiconductor layer. Accordingly, even if the stress is applied to the second semiconductor layer owing to the expansion and the contraction of the support caused by the heat applied while the buried insulating layer is buried in lieu of the first semiconductor layer, the stress applied to the second semiconductor layer can be relaxed by the cavity portions. As such, such a semiconductor device can be provided that the differences of properties (specifically, of the mobility) in transistors can be suppressed.

### BRIEF DESCRIPTION OF THE DRAWINGS

The invention will be described with reference to the accompanying drawings, wherein like numbers reference like elements.

FIGS. 1A and 1B are pattern diagrams of an embodiment illustrating a process of a method for manufacturing a semiconductor substrate in sequence. FIG. 1A is a pattern diagram in plan illustrating the method for manufacturing the semiconductor substrate and FIG. 1B is a pattern diagram in cross section illustrating the method for manufacturing the semiconductor substrate.

FIGS. 2A and 2B are pattern diagrams illustrating the method of manufacturing the semiconductor substrate. FIG. 2A is a pattern diagram in plan illustrating the method for manufacturing the semiconductor substrate and FIG. 2B is a pattern diagram in cross section illustrating the method for manufacturing the semiconductor substrate.

FIGS. 3A and 3B are pattern diagrams illustrating the method for manufacturing the semiconductor substrate. FIG. 3A is a pattern diagram in plan illustrating the method for manufacturing the semiconductor substrate and FIG. 3B is a pattern diagram in cross section illustrating the method for manufacturing the semiconductor substrate.

FIGS. 4A and 4B are pattern diagrams illustrating the method for manufacturing the semiconductor substrate. FIG. 4A is a pattern diagram in plan illustrating the method for manufacturing the semiconductor substrate and FIG. 4B is a pattern diagram in cross section illustrating the method for manufacturing the semiconductor substrate.

FIGS. 5A and 5B are pattern diagrams illustrating the method for manufacturing the semiconductor substrate. FIG. 5A is a pattern diagram in plan illustrating the method for manufacturing the semiconductor substrate and FIG. 5B is a pattern diagram in cross section illustrating the method for manufacturing the semiconductor substrate.

FIGS. 6A and 6B are pattern diagrams illustrating the method for manufacturing the semiconductor substrate. FIG. 6A is a pattern diagram in plan illustrating the method for manufacturing the semiconductor substrate and FIG. 6B is a pattern diagram in cross section illustrating the method for manufacturing the semiconductor substrate.

FIGS. 7A and 7B are pattern diagrams illustrating the method for manufacturing the semiconductor substrate. FIG. 7A is a pattern diagram in plan illustrating the method for manufacturing the semiconductor substrate and FIG. 7B is a pattern diagram in cross section illustrating the method for manufacturing the semiconductor substrate.

FIGS. 8A and 8B are pattern diagrams illustrating the method for manufacturing the semiconductor substrate. FIG. 8A is a pattern diagram in plan illustrating the method for manufacturing the semiconductor substrate and FIG. 8B is a pattern diagram in cross section illustrating the method for manufacturing the semiconductor substrate.

FIGS. 9A and 9B are pattern diagrams illustrating a method for manufacturing the semiconductor device and a structure of the semiconductor device manufactured thereby. FIG. 9A is a pattern diagram in plan and FIG. 9B is a pattern diagram in cross section.

FIG. 10 is a pattern diagram in cross section illustrating a method for manufacturing the known semiconductor substrate.

### DESCRIPTION OF EXEMPLARY EMBODIMENTS

Explained hereinafter are embodiments of a method for manufacturing a semiconductor substrate, and a method for manufacturing a semiconductor device and a semiconductor device manufactured thereby according to the invention, referring to the attached drawings.

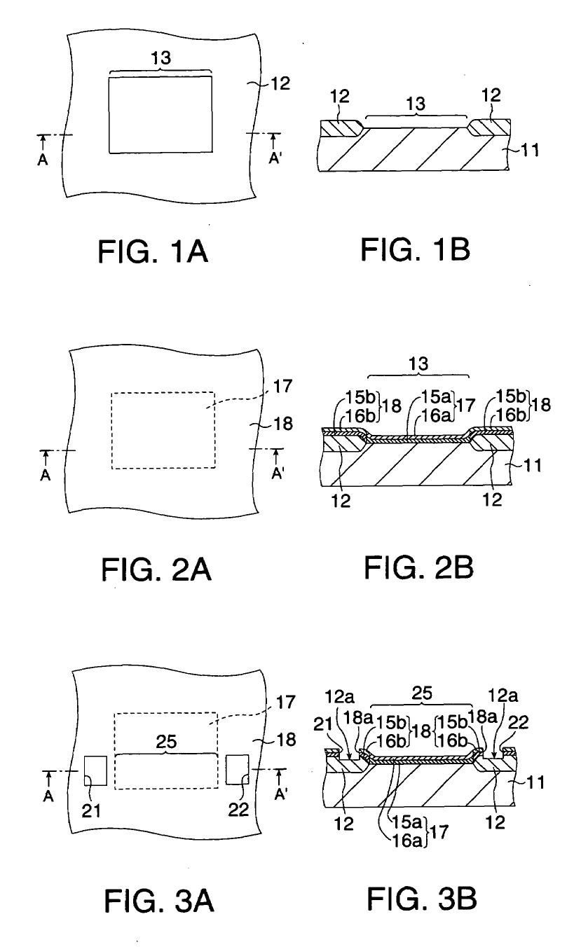

FIGS. 1 to 8 are pattern diagrams illustrating the method for manufacturing the semiconductor substrate. FIGS. 1A, 2A, 3A, 4A, 5A, 6A, 7A and 8A are pattern diagrams in plan, and FIGS. 1B, 2B, 3B, 4B, 5B, 6B, 7B and 8B are pattern diagrams in cross section taken along a line A-A′ of the respective corresponding pattern diagrams in plan. Hereinafter, the method for manufacturing the semiconductor substrate is explained with reference to FIGS. 1 to 8.

In a process as illustrated in FIGS. 1A and 1B, an element isolation layer 12 is formed on a silicon substrate 11 as a semiconductor base material (a bulk silicon substrate). The element isolation layer 12 is, for example, a LOCOS (Local Oxidation of Silicon). The element isolation layer 12 is provided in order to establish an electrical isolation between a SOI element forming region 13 serving as an element region on which a transistor of a SOI structure is formed and a bulk element forming region (not shown here) on which a transistor of a bulk structure is formed. An explanation of the bulk element forming region will be omitted here. Initially, a silicon oxide film (SiO2), which is not shown here, is formed on an entire surface of the silicon substrate 11. Then, a silicon nitride film (SiN), which is not shown here, is formed on the silicon substrate 11 of the SOI element forming region 13 using a photo-lithography technique. Subsequently, regions of the silicon substrate 11 other than the SOI element forming region 13 as the other region is oxidized using the silicon nitride film as a mask. Accordingly, the element isolation layer 12 is formed on the regions of the silicon substrate 11 other than the SOI element forming region 13.

In a process as illustrated in FIGS. 2A and 2B, a silicon germanium (SiGe) layer 15 serving as a first semiconductor layer and a silicon (Si) layer 16 serving as a second semiconductor layer are formed in this order on the entire surface of the silicon substrate 11. Initially, the silicon oxide film (not shown here) on the silicon substrate 11 of the SOI element forming region 13 is removed using the photo-lithography technique. Accordingly, only the silicon substrate 11 of the SOI element forming region 13 is exposed.

Then, the silicon germanium layer 15 serving as a sacrifice layer and the silicon layer 16 for forming a SOI element are grown on the entire surface of the silicon substrate 11 in this order by employing an epitaxial growth technique. Accordingly, a newly grown single crystal epitaxial film 17 which inherits a crystallinity of the silicon substrate 11 is formed on the region where the silicon substrate 11 is exposed. The single crystal epitaxial film 17 is composed of a first silicon germanium layer 15a and a first silicon layer 16a which are grown into single crystal. On the other hand, a polycrystalline epitaxial film 18 is formed on the element isolation layer 12. The polycrystalline epitaxial film 18 is composed of a second silicon germanium layer 15b and a second silicon layer 16b which are grown into polycrystalline.

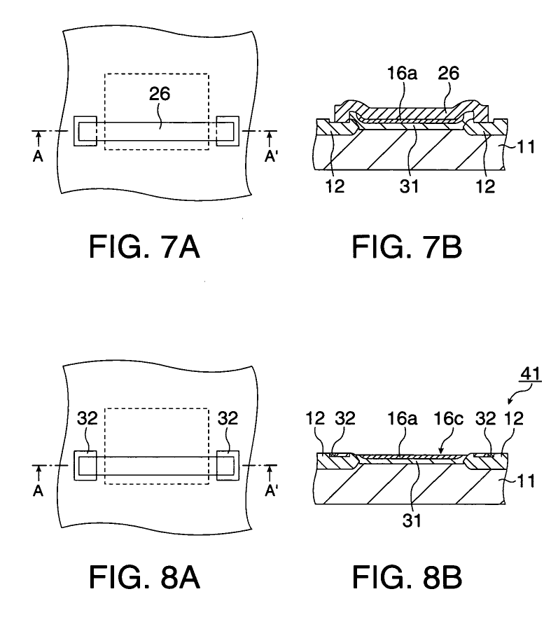

In a process as illustrated in FIGS. 3A and 3B, a first support hole 21 and a second support hole 22 are formed on the element isolation layer 12. The first support hole 21 and the second support hole 22 are positioned at first regions on the element isolation layer 12, such that a stress applied to the first silicon layer 16b can be relaxed even if a support 26 (see FIGS. 7A and 7B) is deformed by heat evolved in a subsequent process of forming a buried insulating layer 31 (see FIG. 7B).

More specifically, owing to a formation of the first support hole 21 and the second support hole 22 on the element isolation layer 12, portions of the polycrystalline epitaxial film 18 are left between the support 26 and side surfaces of the single crystal epitaxial film 17 when the support 26 is formed (see FIGS. 5A and 5B). Accordingly, when the first silicon germanium layer 15a is removed by an etching process in order to create a first cavity portion 29 (see FIG. 6B), thus left portions of the polycrystalline epitaxial film 18 are removed together with the first silicon germanium layer, resulting in forming second cavity portions (see FIG. 6B) which serves as buffering regions between the support 26 and side surfaces of the first silicon layer 16a. These second cavity portions 30 serve to release therewithin the stress applied to the first silicon layer 16a. That is, the first -support hole 21 and the second support hole 22 are formed at such positions where the second cavity portions 30 capable of providing a relaxation of the stress applied to the first silicon layer 16a are created on the element isolation layer 12 at positions of side portions of the first silicon layer 16a.

Initially, a resist pattern (not shown here) including openings corresponding to the regions of the first support hole 21 and the second support hole 22 is formed using the photo-lithography technique. Then, portions of a second silicon layer 16b, a second silicon germanium layer 15b and the element isolation layers 12 are removed by the etching process by using this resist pattern as a mask, the portions corresponding to each of the support holes 21, 22.

As stated above, the first support hole 21 and the second support hole 22 are formed on the element isolation layer 12. Further, a creation of the first support hole 21 and the second support hole 22 contributes to an exposure of end surfaces 18a of the polycrystalline epitaxial film 18 and to an exposure of surfaces 12a of the element isolation layer 12 as well. In the meantime, the region where the single crystal epitaxial film 17 is formed thereon in the region between the first support hole 21 and the second support hole 22 is an element forming region 25.

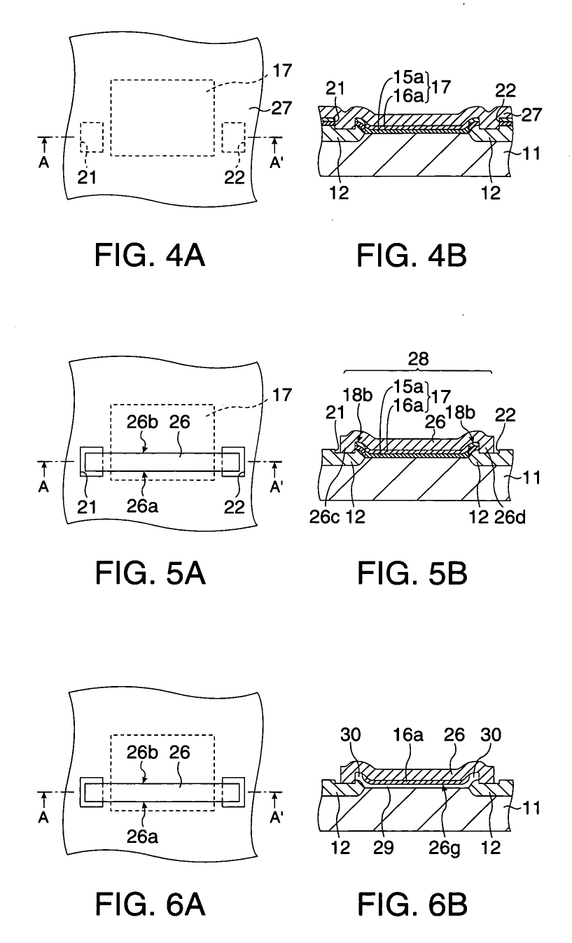

In a process as illustrated in FIGS. 4A and 4B, a support forming layer 27 for forming the support 26 is formed (see FIGS. 5A and 5B) on the entire surface of the silicon substrate 11 in such a manner that the support holes 21, 22 and the silicon layer 16a are covered by the support forming layer 27. An example of the support forming layer 27 includes a silicon oxide film (SiO₂). Initially, the resist pattern used in the prior process is removed. Then, the support forming layer 27 made, for example, of silicon oxide film (SiO₂) is buried into the first support hole 21 and the second support hole 22, for example, by a CVD (Chemical Vapor Deposition) method or the like and is formed on the entire surface of the silicon substrate 11 so as to cover the silicon layer 16 as well.

In a process as illustrated in FIGS. 5A and 5B, portions of the support forming layer 27 for forming the support 26 other than the support forming region 28 are removed to accomplish the support 26. The etching process is employed to remove the portions of the support forming layer 27 by using the resist pattern including openings at portions other than a plane shaped region of the support 26 (not shown here) as a mask. Further, using the same resist pattern as a mask, portions of the single crystal epitaxial film 17 and portions of the polycrystalline epitaxial film 18 other than the support forming region 28 are removed by the etching process.

As stated above, the support 26 is formed on the basis of the support forming layer 27 to have a first side surface 26a and a second side surface 26b of the support 26 (see FIGS. 5A for both) be exposed. Further, portions 18b of the polycrystalline epitaxial film 18 reside between the support 26 and the single crystal epitaxial film 17. Still further, the single crystal epitaxial film 17 (the first silicon layer 16a and the first silicon germanium layer 15a) below the first side surface 26a and the second side surface 26b of the support 26 and side surfaces of the portions 18b of the polycrystalline epitaxial film 18 (the second silicon layer 16b and the second silicon germanium layer 15b) are exposed.

Also, in forming the first support hole 21 and the second support hole 22, a formation of grooves above upper portions of the element isolation layer 12 enables an exposure of surfaces 12a of the element isolation layer 12 (see FIG. 3B), such that base portions 26c, 26d of the support 26 and the element isolation layer 12 are securely brought into contact with each other for a fixation. Accordingly, a detachment of the support 26 from the element isolation layer 12 is avoidable.

In a process as illustrated in FIGS. 6A and 6B, the first silicon germanium layer 15a and the portions 18b of the polycrystalline epitaxial film 18 below the support 26 (see FIG. 5B for both) are removed selectively, for example, by a wet etching process. Initially, the resist pattern used in the prior process is removed. Then, the single crystal epitaxial film 17 and the portions 18b of the polycrystalline epitaxial film 18 below the support 26 are brought into contact with an etching agent such as a fluoronitoric acid and a nitric acid mixture. At the time, the portions where the single crystal epitaxial film 17 and the polycrystalline epitaxial film 18 are exposed (the exposed surfaces below the first side surface 26a and the second side surface 26b of the support 26) are priory etched. Since the first silicon layer 16a has an etching selection ratio smaller than that of the first silicon germanium layer 15a, it is possible to selectively remove the first silicon germanium layer 15a, with the first silicon layer 16a being left.

Additionally, portions 18b of the polycrystalline epitaxial film 18 below the support 26 (the portions of the second silicon layer 16b and the portions of the second silicon germanium layer 15b) are polycrystalized, such that the portions 18b, having an etching rate higher than that of the first silicon layer 16a of single crystal, are removed together. In view of the above, a hollow first cavity portion 29 is created between the silicon substrate 11 and the first silicon layer 16a (the sides of the first silicon layer 16a) and the second cavity portions 30 are also created between the support 26 and the side surfaces of the first silicon layer 16a (the sides of the first silicon layer 16a) as well. In the meantime, the first silicon layer 16a is supported owing to a close contact with a lower surface 26g of the support 26.

In a process as illustrated in FIGS. 7A and 7B, a buried insulating layer (BOX layer: Buried Oxide layer) 31 is formed in the first cavity portion 29 (see FIG. 6B). An example of the buried insulating layer 31 includes a silicon oxide film. By using a thermal oxidation method, silicon and oxygen contained in the silicon substrate 11 and the first silicon layer 16a react each other to form the buried insulating layer 31.

Further, owing to the thermal oxidation, the support 26 is heated to have the support expand and contract, resulting in applying the stress to the first silicon layer 16a which is supported by the support 26. However, since the second cavity portions 30 (see FIG. 6B) are formed between the sides of the first silicon layer 16a and the support 26, the stress applied to the first silicon layer 16a (stress applied in a side surface direction or in a plane direction) can be relaxed within the second cavity portions 30 (the buffering regions). Further, with the thermal oxidation method, the buried insulating layer 31 is formed, for example, in the second cavity portions 30 in addition to the first cavity portion 29.

In a process as illustrated in FIGS. 8A and 8B, a semiconductor substrate 41 is completed. Initially, in order to provide the electrical insulation with the SOI element, an insulation film 32 composed of a silicon oxide film is formed on the entire surface of the silicon substrate 11. The insulation film 32 is formed, for example, by a CVD method. Then, the polycrystalline epitaxial film 18, which is on the element isolation layer 12 but not shown here, is used as a stopper layer for a planarization (a planarization treatment) of the entire surface of the silicon substrate 11 by means of CMP polishing (Chemical Mechanical Polishing). Accordingly, the insulation film 32 and the support 26 are partially removed. Subsequently, useless portions of the support 26, portions of the insulation film 32 and the polycrystalline epitaxial film 18 are further removed up to an upper surface 16c of the first silicon layer 16a. As such, the upper surface 16c of the first silicon layer 16a is exposed and a structure in which the first silicon layer 16a is elementally separated by the buried insulating layer 31 is provided with the silicon substrate 11 (SOI structure), resulting in a completion of the semiconductor substrate 41.

As stated above, according to this method for manufacturing the semiconductor substrate 41, since the first support hole 21 and the second support hole 22 are formed on the element isolation layer 12, such a structure can be achieved that there are portions 18b of the polycrystalline epitaxial film 18 between the base portions 26c, 26d of the support 26 and the single crystal first silicon layer 16a. Therefore, when the first silicon germanium layer 15a is removed by the etching process, the portions 18b of the polycrystalline epitaxial film 18 can be removed together with the first silicon germanium layer 15a. Accordingly, even if the support 26 expands and contracts by heat applied while the buried insulating layer 31 is buried within the first cavity portion 29, the stress applied to the first silicon layer 16a can be relaxed (released) owing to the second cavity portions 30.

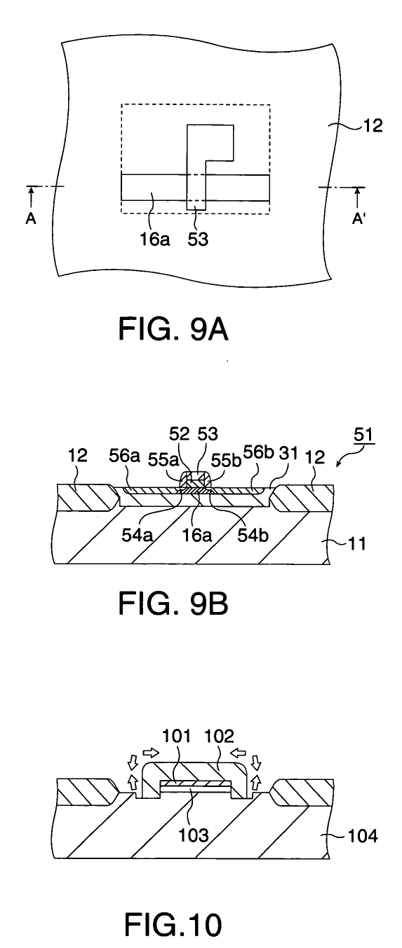

FIGS. 9A and 9B are pattern diagrams illustrating the method for manufacturing the semiconductor device and a structure of the semiconductor device. FIG. 9A is a pattern diagram in plan and FIG. 9B is a pattern diagram in cross section taken along a line A-A′ of FIG. 9A. Explained hereinafter is the method for manufacturing the semiconductor device and the structure of the semiconductor device, referring to FIGS. 9A and 9B. In the meantime, the method for manufacturing the semiconductor device of FIGS. 9A and 9B is conducted subsequent to the methods for manufacturing the semiconductor substrate which were explained by FIGS. 1 to 8.

In a process as illustrated in FIGS. 9A and 9B, the semiconductor device 51 is completed. Initially, the surface of the first silicon layer 16a is subjected to a thermal oxidation process to form a gate insulation film 52 on the surface of the first silicon layer 16a. Then, the polycrystalline silicon layer is formed on the gate insulation film 52, for example, by the CVD method. Subsequently, the polycrystalline silicon layer is patterned using the photo-lithography technique to form a gate electrode 53 on the gate insulation film 52.

Next, using the gate electrode 53 as a mask, impurities such as As (arsenic), phosphorous (P) and boron (B) are ion injected to the first silicon layer 16a in order to form LDD layers 54a, 54b composed of low concentration impurity introduction layers arranged both sides of the gate electrode 53 on the first silicon layer 16a. Then, an insulation layer is formed, for example, by the CVD method, on the first silicon layer 16a on which the LDD layers 54a, 54b are formed. The insulation layer is etched back through a dry etching process such as RIE to form side walls 55a, 55b on side walls of the gate electrode 53, respectively.

Then, using the gate electrode 53 and the side walls 55a, 55b as masks, impurities such as As, P and B are ion injected into the first silicon layer 16a. Accordingly, source/drain electrode layers 56a, 56b composed of high concentration impurity introduction layers are formed aside the side walls 55a, 55b of the first silicon layer 16a, resulting in completing a transistor. Additionally, a formation of the bulk element on the bulk element forming region contributes to a completion of a semiconductor device 51 including both of the SOI element and the bulk element on the silicon substrate 11.

As stated above, the stress applied to the first silicon layer 16a can be suppressed and thus it is possible to provide the method for manufacturing the semiconductor device and the semiconductor device manufactured thereby in which differences of properties in transistors can be suppressed.

As stated above into details, the method for manufacturing the semiconductor substrate and the method for manufacturing the semiconductor device and the semiconductor device manufactured thereby according to the embodiments produce the following advantageous results.

According to an aspect of the invention, the first support hole 21 and the second support hole 22 are formed at the regions on the element isolation layer 12, and thereby the portions 18b of the polycrystalline epitaxial film 18 can be left between the base portions 26c, 26d of the support 26 and the first silicon layer 16a. Accordingly, when the first silicon germanium layer 15a is removed by the etching process, the portions 18b of the polycrystalline epitaxial film 18 can be removed together with the first silicon germanium layer and the second cavity portions 30 can be formed aside the both sides of the first silicon layer 16a. With the above stated structure, if the stress is applied to the first silicon layer 16a because of the expansion and the contraction of the support 26 due to the heat evolved while the buried insulating layer 31 is buried in lieu of the first silicon germanium layer 15a, the stress applied to the first silicon layer 16a can be released by the second cavity portions 30. As a result thereof, the stress applied to the first silicon layer 16a is relaxed to suppress an occurrence of differences of properties (specifically, of the mobility) in transistors.

In the meantime, the embodiment is not limited to the above statement but can be carried out by the following manner.

Modification 1

Instead of the processes that the buried insulating layer 31 is buried in lieu of the first silicon germanium layer 15a and an identical insulation layer 31 is buried aside the both sides of the first silicon layer 16a in a manner as stated above, cavities can be left at both sides of the first silicon layer 16a. With such an structure, if the support 26 expands and contracts due to the heat applied in the course of the continuous processes after the buried insulating layer 31 is formed, the stress applied to the first silicon layer 16a can be relaxed owing to the cavities.

Modification 2

Silicon was exemplified as a material for the semiconductor base material in the above embodiment; however, the material is not limited to the silicon but may includes, for example, Ge, SiGe, SiC, SiSn, PbS, GaAs, InP, GaP, GaN, ZnSe or the like.

Modification 3

The silicon germanium is exemplified as a material for the first semiconductor layer and the silicon is exemplified as a material for the second semiconductor layer, respectively, in the above embodiment; however, a combination of the first semiconductor layer and the second semiconductor layer which has the etching selection ratio smaller than that of the first semiconductor layer may be satisfactory. Therefore, a combination of the materials of the first semiconductor layer and the second semiconductor layer may be selected from the materials of, for example, Ge, SiC, SiSn, PbS, GaAs, InP, GaP, GaN, ZnSe or the like.

What is claimed is:

1. A method for manufacturing a semiconductor substrate comprising:
forming an element isolation layer on a semiconductor base material for separating an element region from the other regions;
forming a first semiconductor layer on the semiconductor base material;
forming a second semiconductor layer on the first semiconductor layer, the second semiconductor layer having an etching selection ratio smaller than that of the first semiconductor layer;
forming support holes by removing portions of the first semiconductor layer and the second semiconductor layer, the portions corresponding to regions for the support holes;
forming a support forming layer on the semiconductor base material such that the support holes and the second semiconductor layer are covered by the support forming layer;
forming exposed surfaces such that portions of the support forming layer other than a region including the support holes and the element region are etched to expose a support and portions of end portions of the first semiconductor layer and the second semiconductor layer which are positioned below the support;
forming a first cavity portion between the second semiconductor layer and the semiconductor base material of the element region by etching the first semiconductor layer through the exposed surfaces;
forming a buried insulating layer within the first cavity portion; and
removing portions of the support positioned on the second semiconductor layer by providing a planarization treatment above the second semiconductor layer;
wherein forming the support holes includes forming the support holes at first regions on the element isolation layer.

2. The method for manufacturing the semiconductor substrate according to claim 1, wherein the first regions are regions capable of forming second cavity portions between side surfaces of the second semiconductor layer of the element region and the support while the first cavity portion is formed.

3. The method for manufacturing the semiconductor substrate according to claim 2, wherein the second cavity portions are buffering regions capable of relaxing a stress applied to the second semiconductor layer of the element region while the buried insulating layer is formed.

4. The method for manufacturing the semiconductor substrate according to claim 1, wherein forming the support holes includes forming the support holes at portions where spaces are left between the support and the side surfaces of the second semiconductor layer when the buried insulating layer is buried in the course of forming the buried insulating layer.

5. The method for manufacturing the semiconductor substrate according to claim 1, wherein the first semiconductor layer is a silicon germanium layer and the second semiconductor layer is a silicon layer.

6. A method for manufacturing a semiconductor device comprising:
forming a transistor on the second semiconductor layer after the method of manufacturing the semiconductor substrate according to claim 1 is performed.

7. A semiconductor device having a SOI structure comprising:
a buried insulating layer buried on a semiconductor base material in lieu of a first semiconductor layer;
a second semiconductor layer formed on the buried insulating layer;
a support for supporting the second semiconductor layer; and
a portion of a supporting hole formed at first regions on an element isolation layer.
